(19) United States
(12) Patent Application Publication
(10) Pub. No.: US 2024/0232479 A1
(43) Pub. Date: Jul. 11, 2024

(54) Integrated Deep Learning Workflow for Geologically Sequestered CO2 Monitoring

(71) Applicant: Schlumberger Technology Corporation, Sugar Land, TX (US)

(72) Inventors: Wenyi Hu, Fulshear, TX (US); Son Phan, Houston, TX (US); Cen Li, Missouri City, TX (US); Aria Abubakar, Sugar Land, TX (US); Zhun Li, Houston, TX (US)

(21) Appl. No.: 18/408,163

(22) Filed: Jan. 9, 2024

Related U.S. Application Data
(60) Provisional application No. 63/479,124, filed on Jan. 9, 2023.

(51) Int. Cl. G06F 30/28; G06F 30/27

(52) U.S. Cl. CPC G06F 30/28; G06F 30/27

(57) ABSTRACT

An integrated workflow is presented including a suite of data-driven technologies that aims to substantially reduce the cost of monitoring data acquisition, improve the robustness and efficiency of time-lapse data processing procedures to shorten the turnaround time of projects utilizing seismic data for monitoring sub-surface fluid reservoirs. In particular, plumes of subsurface CO₂ may be monitored, including CO₂ deliberately injected into the sub-surface as a sequestration technique. The workflow may include two parts: (1) cost-effective data acquisition schemes and (2) efficient data processing algorithms. The technology components in the workflow may include deep learning sparse monitoring data reconstruction and optimal acquisition survey design, deep learning deblending of simultaneous source monitoring data, time-lapse data repeatability enforcement through deep learning, and rapid CO₂ plume body and property estimation directly from pre-migration monitoring data.

### CROSS-REFERENCE TO RELATED APPLICATIONS

This application claims priority to U.S. Provisional Patent Application No. 63/479,124, filed on Jan. 9, 2023, which is incorporated herein by reference in its entirety.

### BACKGROUND

Long-term monitoring of geologically sequestered CO₂, which can range from e.g., 10 years to over 100 years (though not limited to this range), may be used to assess the security of carbon capture and storage (CCS). Time-lapse seismic is one of the most effective methods for CO₂ monitoring.

However, the main challenge in time-lapse monitoring of subsurface conditions is the high cost associated with the data acquisition and the subsequent time-lapse data processing. Assessment of 4D seismic repeatability and CO₂ detection limits using a sparse permanent land array at the Aquistore CO₂ storage site. For CO₂ sequestration projects, after a baseline dataset is acquired, a monitoring data acquisition survey needs to be conducted, for example, every 2-5 years to monitor the movement of the CO₂ plume body. Modern seismic data acquisition surveys are expensive due to industry requirements for finer spatial sampling and wide azimuth illumination, etc. Time-lapse seismic data processing is a time-consuming and labor-intensive procedure consisting of many requirements including construction of an accurate earth model, detailed signal processing steps, imaging and inversion. Compared to general seismic data processing, an additional challenge in time-lapse data processing is how to suppress the non-repeatability between the baseline data and the monitoring data, an inevitable problem due to seasonal changes in tides and near-surface conditions and changing seismic attributes from survey to survey, etc.

Deep learning is powerful and flexible for cost reduction of seismic data acquisition and processing. However, because most of the existing deep learning research efforts on this topic are for general seismic data instead of time-lapse, there is a major concern about network generalization. As such, there is a need for a method, system, and workflow that focuses on time-lapse data.

### SUMMARY

The computing systems, methods, processing procedures, techniques and workflows disclosed herein are more efficient and/or effective methods for identifying, isolating, transforming, and/or processing various aspects of seismic signals or other data that is collected from a subsurface region or other multi-dimensional space.

In some embodiments, a method includes implementing a deep learning workflow that includes: deep learning sparse monitoring data reconstruction and optimal acquisition survey design, deep learning deblending of simultaneous source monitoring data, deep learning algorithms for coherent and incoherent noise removal or suppression, automatic interpretation of subsurface CO₂ plume body and the corresponding subsurface property changes from seismic images, seismic image resolution enhancement for accurate CO₂ plume body interpretation, rapid CO₂ plume body and property estimation directly from pre-migration monitoring data, deep learning-based 2D-to-3D image conversion, multi-physics multi-type data integration, and CO₂ plume body and property forecasting.

In some embodiments, a computing system displays any of the seismic data, the noise, and the active data treated as noise.

In some embodiments, a computing system is provided that includes at least one processor, at least one memory, and one or more programs stored in the at least one memory. The programs include instructions, which when executed by the at least one processor, are configured to perform any method disclosed herein.

In some embodiments, a computer readable storage medium is provided, which has stored therein one or more programs, the one or more programs include instructions, which when executed by a processor, cause the processor to perform any method disclosed herein.

In some embodiments, a computing system is provided that includes at least one processor, at least one memory, and one or more programs stored in the at least one memory, and means for performing any method disclosed herein.

In some embodiments, an information processing apparatus for use in a computing system is provided, and that includes means for performing any method disclosed herein.

These systems, methods, processing procedures, techniques, and workflows increase effectiveness and efficiency. Such systems, methods, processing procedures, techniques, and workflows may complement or replace conventional methods for identifying, isolating, transforming, and/or processing various aspects of seismic signals or other data that is collected from a subsurface region or other multi-dimensional space.

In an embodiment, a method includes collecting a baseline dataset including seismic data for a subterranean formation that includes a fluid reservoir, collecting an initial monitoring dataset including seismic data, training a time-lapse fluid reservoir monitoring deep learning model with a set of inputs including the baseline dataset, collecting a later monitoring dataset including seismic data at a time subsequent to the collection of the baseline dataset and initial monitoring dataset, assessing, utilizing the time-lapse fluid reservoir monitoring deep learning model, a change in the fluid reservoir between the collection of either the baseline dataset or the initial monitoring dataset and the collection of the later monitoring dataset, and providing a user with a data plot representing the change in the fluid reservoir. In this method, the data plot representing the change in the fluid reservoir is a graphical display and the method further includes performing a worksite action in response to the assessed change in the fluid reservoir. The worksite action includes generating and transmitting a signal that causes a physical action to occur at the fluid reservoir. The training of the deep learning model and assessing using the deep learning model may utilize a sparse monitoring data reconstruction and optimal acquisition survey design, the deep learning model may include one or more algorithms for coherent and incoherent noise removal or suppression, the deep learning model may include 2D-to-3D image conversion and the data plot may include an interpretation of a subsurface CO₂ plume body. Further to the described method, it may also include interpreting a subsurface CO₂ plume body based on the change in the fluid reservoir, enhancing a resolution of the data plot to improve interpretation of the CO₂ plume body, and integrating multi-physics and multi-type data to the deep learning model. The method may also include estimating a CO₂ plume body property from a pre-migration monitoring dataset, the estimation being rapid, and forecasting the CO₂ plume body.

In the embodiment discussed above, the fluid reservoir may be a carbon dioxide (CO₂) sequestration region. Further, the fluid reservoir monitoring deep learning model may be a convolutional neural network. The embodiment may also include activating a plurality of seismic sources, and recording, utilizing a plurality of receivers, signals from the seismic sources. The later monitoring dataset includes the recorded signals. The method presented above may also include training a deblending deep learning model to deblend the recorded signals, the deblending training. This deblending may include identifying a relation between an unblended monitoring signal and the recorded signals. The relation is a deblended output, and providing the deblended output to a one of a supervised network, a self-supervised network or an unsupervised network that utilizes a blending loss function. The result is a finetuned deblended output, deblending the recorded signals of the later monitoring dataset utilizing the deblending deep learning model. The later monitoring dataset includes the result of the deblending.

The above embodiment may include a time that the later monitoring dataset is collected that is at least one year subsequent to the collection of the baseline dataset.

The embodiment may also include reducing at least one of a data acquisition cost and a data processing cost by collecting initial monitoring and later monitoring datasets which are much smaller in size than the baseline dataset.

In another embodiment, a method is presented that includes collecting a baseline dataset including seismic data for a subterranean formation that includes a carbon dioxide (CO₂) sequestration region, collecting an initial monitoring dataset including seismic data for the CO₂ sequestration region, training a time-lapse fluid reservoir monitoring deep learning model with a set of inputs including the baseline dataset, collecting a later monitoring dataset at a time subsequent to the collection of the baseline dataset and initial monitoring dataset, assessing, utilizing the time-lapse fluid reservoir monitoring deep learning model, a change in the CO₂ sequestration region between the collection of either the baseline dataset or the initial monitoring dataset and the collection of the later monitoring dataset, and providing a user with a data plot representing the change in the CO₂ sequestration region. Collecting the baseline dataset, the initial monitoring dataset and the later monitoring dataset includes activating one or more seismic sources and recording signals from the seismic sources at a plurality of receivers. The baseline dataset, the initial monitoring dataset and the later monitoring dataset each includes the recorded signals. In this embodiment, the data plot representing the change in the CO₂ sequestration region may be a graphical display and the method may further include performing a worksite action in response to the assessed change in the CO₂ sequestration region, The worksite action includes generating and transmitting a signal that causes a physical action to occur at the CO₂ sequestration region. In this embodiment, more receivers may be used to record the baseline dataset than are used to record the initial monitoring dataset and the later monitoring dataset. In addition, the fluid reservoir monitoring deep learning model is a convolutional neural network.

In the above embodiment, the recorded signals include blended signals from the one or more seismic sources, the method may further include training a deblending deep learning model to deblend the recorded signals. The deblending training may include identifying a relation between an unblended monitoring signal and the recorded signals. The relation is a deblended output, providing the deblended output to one of a supervised network, a self-supervised network or an unsupervised network that utilizes a blending loss function. The result is a finetuned deblended output, deblending the recorded signals of the later monitoring dataset utilizing the deblending deep learning model. In this embodiment the time that later monitoring dataset is collected is at least one year subsequent to the collection of the baseline dataset. This embodiment may also include reducing at least one of a data acquisition cost and a data processing cost by collecting initial monitoring and later monitoring datasets which are much smaller in size than the baseline dataset. Assessing changes in the CO₂ sequestration region may include enhancing a resolution of a seismic image.

Another embodiment is a method including collecting a dense baseline dataset including seismic data for a carbon dioxide (CO₂) sequestration region, collecting an initial monitoring dataset including seismic data for the CO₂ sequestration region. The initial monitoring dataset is significantly smaller than the dense baseline dataset, training a time-lapse CO₂ monitoring deep learning model with a set of inputs including the dense baseline dataset and the initial monitoring dataset. The CO₂ monitoring deep learning model is a convolutional neural network, collecting a later monitoring dataset at a time that is at least one year subsequent to the collection of the baseline dataset, the later monitoring dataset including a plurality of recorded signals. The later monitoring dataset is significantly smaller than the dense baseline dataset, training a two-stage deblending deep learning model to deblend the plurality of simultaneously recorded monitoring signals, the deblending training including identifying in a first stage of the two-stage deblending deep learning model a relation between an unblended monitoring signal and the simultaneously recorded monitoring signals. The relation is a first stage deblended output; providing the first stage deblended output to a second stage of the two-stage deblending deep learning model. The second stage is self-supervised; deblending the plurality of seismic signals of the later monitoring dataset utilizing the two-stage deblending deep learning model to create a deblended later monitoring dataset; assessing, utilizing the time-lapse CO₂ monitoring deep learning model, a change in a CO₂ plume body located in the CO₂ sequestration region between the collection of the dense baseline dataset and the collection of the later monitoring dataset. The assessment includes seismic image resolution enhancement; displaying the change in the CO₂ plume body; and performing a worksite action in response to the assessed change in the CO₂ plume body. The worksite action includes generating and transmitting a signal that causes a physical action to occur at the CO₂ sequestration region.

### BRIEF DESCRIPTION OF THE DRAWINGS

The figures described below are not necessarily to scale; dimensions may be altered to help clarify or emphasize certain features.

FIG. 1 illustrates an example of a computing system that may be used in connection with the drilling system.

FIG. 2 illustrates a seismic measuring unit in an environment in which seismic measuring may take place.

FIG. 3 illustrates a drilling rig in a drilling environment where seismic measuring may also take place.

FIG. 4 illustrates a drilling rig in a drilling environment where seismic measuring may also take place.

FIG. 5 illustrates a drilling rig in a drilling environment where seismic measuring may also take place.

FIG. 6 illustrates, in a vertical plan cross-sectional view, a seismic measuring unit and several drilling rigs in an environment where drilling and seismic measuring is taking place.

FIG. 7 illustrates, in a isometric cross-sectional view, an oil field where various techniques and applications described herein take place.

FIG. 8 illustrates, in a vertical plan cross-sectional view, a marine-based survey of a subterranean subsurface.

FIGS. 9A and 9B illustrate a schematic, flow-chart view of procedures and equipment to improve the robustness and efficiency of time-lapse data processing procedures to shorten the turnaround time of CO₂ monitoring projects.

FIG. 10A illustrates a schematic, flow-chart view of a two-stage monitoring data deblending network.

FIG. 10B represents the blended monitoring data which is the input of the network shown at FIG. 10A.

FIG. 10C represents the deblended monitoring data which is the output of the network shown at FIG. 10A.

FIG. 10D represents an error output of the network shown at FIG. 10A.

FIGS. 11A and 11B illustrate a schematic, flow-chart view of an optimal data survey design.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc., may be used herein to describe various elements, these elements should not be limited by these terms. These terms are used to distinguish one element from another. For example, a first object or step could be termed a second object or step, and, similarly, a second object or step could be termed a first object or step, without departing from the scope of the invention. The first object or step, and the second object or step, are both objects or steps, respectively, but they are not to be considered the same object or step.

The terminology used in the description of the invention herein is for the purpose of describing particular embodiments and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combination of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context.

Those with skill in the art will appreciate that while some terms in this disclosure may refer to absolutes, e.g., all of the components of a wavefield, all source receiver traces, each of a plurality of objects, etc., the methods and techniques disclosed herein may also be performed on fewer than all of a given thing, e.g., performed on one or more components and/or performed on one or more source receiver traces. Accordingly, in instances in the disclosure where an absolute is used, the disclosure may also be interpreted to be referring to a subset.

### Computing Systems

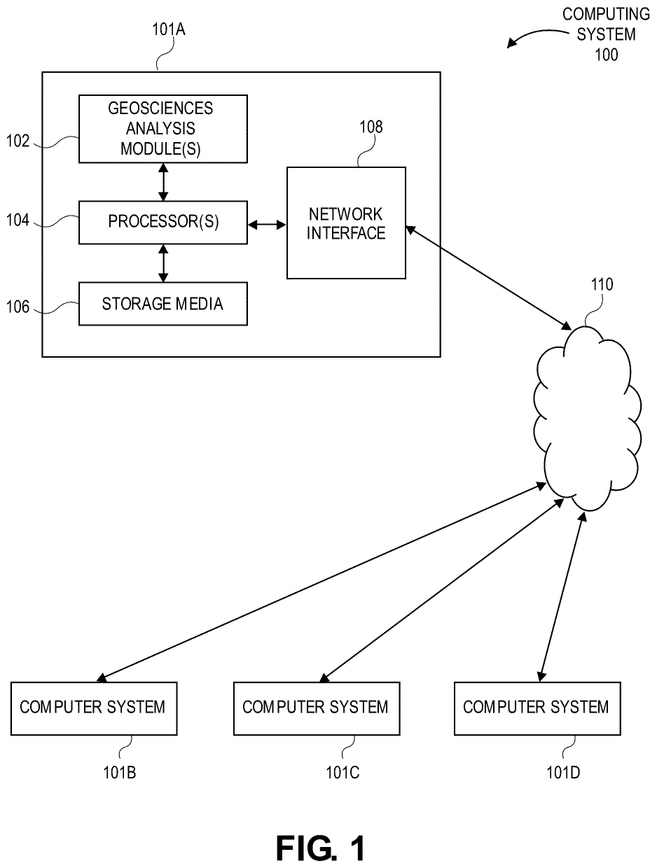

FIG. 1 depicts an example computing system 100 in accordance with some embodiments. The computing system 100 can be an individual computer system 101A or an arrangement of distributed computer systems. The computer system 101A includes one or more geosciences analysis modules 102 that are configured to perform various tasks according to some embodiments, such as one or more methods disclosed herein. To perform these various tasks, geosciences analysis module 102 executes independently, or in coordination with, one or more processors 104, which is (or are) connected to one or more storage media 106. The processor(s) 104 is (or are) also connected to a network interface 108 to allow the computer system 101A to communicate over a data network 110 with one or more additional computer systems and/or computing systems, such as 101B, 101C, and/or 101D (note that computer systems 101B, 101C and/or 101D may or may not share the same architecture as computer system 101A, and may be located in different physical locations, e.g., computer systems 101A and 101B may be on a ship underway on the ocean, while in communication with one or more computer systems such as 101C and/or 101D that are located in one or more data centers on shore, other ships, and/or located in varying countries on different continents). Note that data network 110 may be a private network, it may use portions of public networks, it may include remote storage and/or applications processing capabilities (e.g., cloud computing).

A processor can include a microprocessor, microcontroller, processor module or subsystem, programmable integrated circuit, programmable gate array, or another control or computing device.

The storage media 106 can be implemented as one or more computer-readable or machine-readable storage media. Note that while in the example embodiment of FIG. 1 storage media 106 is depicted as within computer system 101A, in some embodiments, storage media 106 may be distributed within and/or across multiple internal and/or external enclosures of computing system 101A and/or additional computing systems. Storage media 106 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks;

other magnetic media including tape; optical media such as compact disks (CDs) or digital video disks (DVDs), BluRays or any other type of optical media; or other types of storage devices. Note that the instructions discussed above can be provided on one computer-readable or machine-readable storage medium, or alternatively, can be provided on multiple computer-readable or machine-readable storage media distributed in a large system having possibly plural nodes and/or non-transitory storage means. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

It should be appreciated that computer system 101A is one example of a computing system, and that computer system 101A may have more or fewer components than shown, may combine additional components not depicted in the example embodiment of FIG. 1, and/or computer system 101A may have a different configuration or arrangement of the components depicted in FIG. 1. The various components shown in FIG. 1 may be implemented in hardware, software, or a combination of both, hardware and software, including one or more signal processing and/or application specific integrated circuits.

It should also be appreciated that while no user input/output peripherals are illustrated with respect to computer systems 101A, 101B, 101C, and 101D, many embodiments of computing system 100 include computer systems with keyboards, mice, touch screens, displays, etc. Some computer systems in use in computing system 100 may be desktop workstations, laptops, tablet computers, smartphones, server computers, etc.

Further, the steps in the processing methods described herein may be implemented by running one or more functional modules in information processing apparatus such as general-purpose processors or application specific chips, such as ASICs, FPGAs, PLDs, or other appropriate devices. These modules, combinations of these modules, and/or their combination with general hardware are included within the scope of protection.

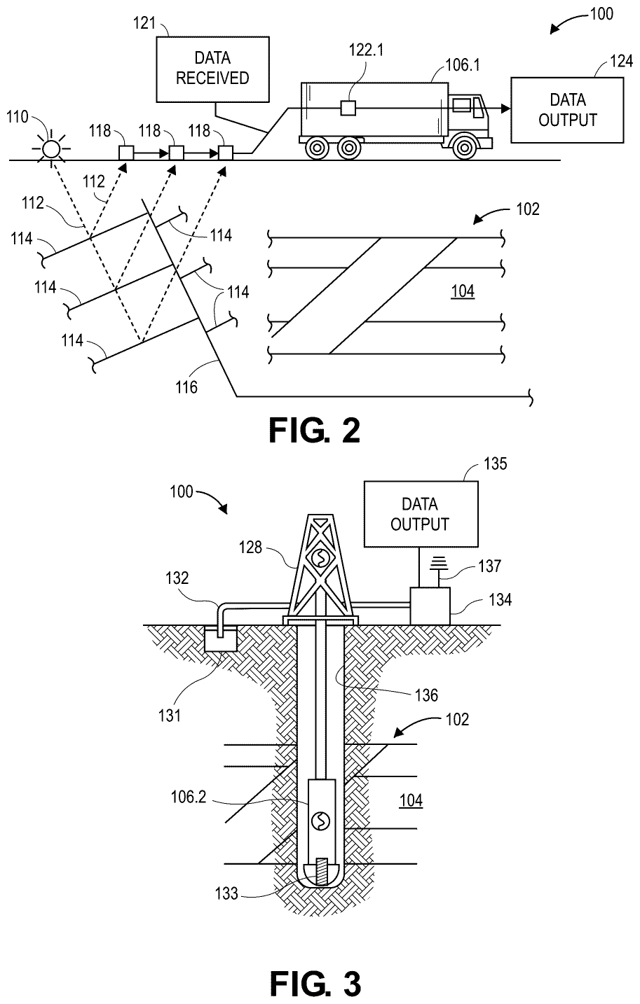

FIGS. 2-5 illustrate simplified, schematic views of oilfield 100 having subterranean formation 102 containing reservoir 104 therein in accordance with implementations of various technologies and techniques described herein.

FIG. 2 illustrates a survey operation being performed by a survey tool, such as seismic truck 106.1, to measure properties of the subterranean formation. The survey operation is a seismic survey operation for producing sound vibrations. In FIG. 2, one such sound vibration, e.g., sound vibration 112 generated by source 110, reflects off horizons 114 in earth formation 116. A set of sound vibrations is received by sensors, such as geophone-receivers 118, situated on the earth's surface. The data received 120 is provided as input data to a computer 122.1 of a seismic truck 106.1, and responsive to the input data, computer 122.1 generates seismic data output 124. This seismic data output may be stored, transmitted or further processed as desired, for example, by data reduction.

FIG. 3 illustrates a drilling operation being performed by drilling tools 106.2 suspended by rig 128 and advanced into subterranean formations 102 to form wellbore 136. Mud pit 130 is used to draw drilling mud into the drilling tools via flow line 132 for circulating drilling mud down through the drilling tools, then up wellbore 136 and back to the surface. The drilling mud is typically filtered and returned to the mud pit. A circulating system may be used for storing, controlling, or filtering the flowing drilling mud. The drilling tools are advanced into subterranean formations 102 to reach reservoir 104. Each well may target one or more reservoirs. The drilling tools are adapted for measuring downhole properties using logging while drilling tools. The logging while drilling tools may also be adapted for taking core sample 133 as shown.

Computer facilities may be positioned at various locations about the oilfield 100 (e.g., the surface unit 134) and/or at remote locations. Surface unit 134 may be used to communicate with the drilling tools and/or offsite operations, as well as with other surface or downhole sensors. Surface unit 134 is capable of communicating with the drilling tools to send commands to the drilling tools, and to receive data therefrom. Surface unit 134 may also collect data generated during the drilling operation and produce data output 135, which may then be stored or transmitted.

Sensors (S), such as gauges, may be positioned about oilfield 100 to collect data relating to various oilfield operations as described previously. As shown, sensor (S) is positioned in one or more locations in the drilling tools and/or at rig 128 to measure drilling parameters, such as weight on bit, torque on bit, pressures, temperatures, flow rates, compositions, rotary speed, and/or other parameters of the field operation. Sensors (S) may also be positioned in one or more locations in the circulating system.

Drilling tools 106.2 may include a bottom hole assembly (BHA) (not shown), generally referenced, near the drill bit (e.g., within several drill collar lengths from the drill bit). The bottom hole assembly includes capabilities for measuring, processing, and storing information, as well as communicating with surface unit 134. The bottom hole assembly further includes drill collars for performing various other measurement functions.

The bottom hole assembly may include a communication subassembly that communicates with surface unit 134. The communication subassembly is adapted to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

Typically, the wellbore is drilled according to a drilling plan that is established prior to drilling. The drilling plan typically sets forth equipment, pressures, trajectories and/or other parameters that define the drilling process for the wellsite. The drilling operation may then be performed according to the drilling plan. However, as information is gathered, the drilling operation may need to deviate from the drilling plan. Additionally, as drilling or other operations are performed, the subsurface conditions may change. The earth model may also need adjustment as new information is collected.

The data gathered by sensors (S) may be collected by surface unit 134 and/or other data collection sources for analysis or other processing. The data collected by sensors (S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 134 may include transceiver 137 to allow communications between surface unit 134 and various portions of the oilfield 100 or other locations. Surface unit 134 may also be provided with or functionally connected to one or more controllers (not shown) for actuating mechanisms at oilfield 100. Surface unit 134 may then send command signals to oilfield 100 in response to data received. Surface unit 134 may receive commands via transceiver 137 or may itself execute commands to the controller. A processor may be provided to analyze the data (locally or remotely), make the decisions and/or actuate the controller. In this manner, oilfield 100 may be selectively adjusted based on the data collected. This technique may be used to optimize (or improve) portions of the field operation, such as controlling drilling, weight on bit, pump rates, or other parameters. These adjustments may be made automatically based on computer protocol, and/or manually by an operator. In some cases, well plans may be adjusted to select optimum (or improved) operating conditions, or to avoid problems.

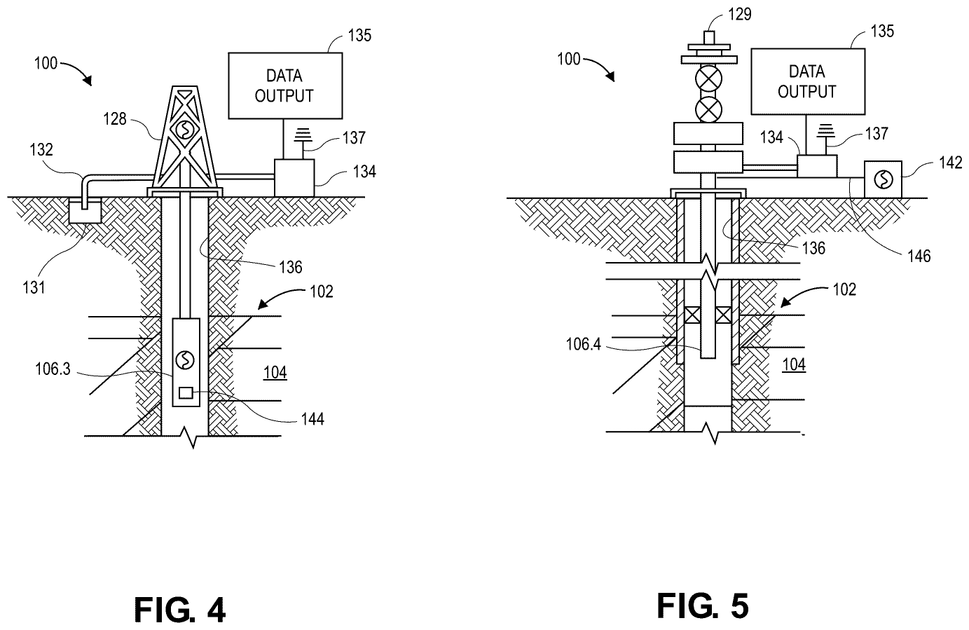

FIG. 4 illustrates a wireline operation being performed by wireline tool 106.3 suspended by rig 128 and into wellbore 136 of FIG. 3. Wireline tool 106.3 is adapted for deployment into wellbore 136 for generating well logs, performing downhole tests and/or collecting samples. Wireline tool 106.3 may be used to provide another method and apparatus for performing a seismic survey operation. Wireline tool 106.3 may for example, have an explosive, radioactive, electrical, or acoustic energy source 144 that sends and/or receives electrical signals to surrounding subterranean formations 102 and fluids therein.

Wireline tool 106.3 may be operatively connected to, for example, geophones 118 and a computer 122.1 of a seismic truck 106.1 of FIG. 2. Wireline tool 106.3 may also provide data to surface unit 134. Surface unit 134 may collect data generated during the wireline operation and may produce data output 135 that may be stored or transmitted. Wireline tool 106.3 may be positioned at various depths in the wellbore 136 to provide a survey or other information relating to the subterranean formation 102.

Sensors (S), such as gauges, may be positioned about oilfield 100 to collect data relating to various field operations as described previously. As shown, sensor S is positioned in wireline tool 106.3 to measure downhole parameters which relate to, for example porosity, permeability, fluid composition and/or other parameters of the field operation.

FIG. 5 illustrates a production operation being performed by production tool 106.4 deployed from a production unit or Christmas tree 129 and into completed wellbore 136 for drawing fluid from the downhole reservoirs into surface facilities 142. The fluid flows from reservoir 104 through perforations in the casing (not shown) and into production tool 106.4 in wellbore 136 and to surface facilities 142 via gathering network 146.

Sensors (S), such as gauges, may be positioned about oilfield 100 to collect data relating to various field operations as described previously. As shown, the sensor (S) may be positioned in production tool 106.4 or associated equipment, such as Christmas tree 129, gathering network 146, surface facility 142, and/or the production facility, to measure fluid parameters, such as fluid composition, flow rates, pressures, temperatures, and/or other parameters of the production operation.

Production may also include injection wells for added recovery. One or more gathering facilities may be operatively connected to one or more of the wellsites for selectively collecting downhole fluids from the wellsite(s).

While FIGS. 2-5 illustrate tools used to measure properties of an oilfield, it will be appreciated that the tools may be used in connection with non-oilfield operations, such as gas fields, mines, aquifers, storage or other subterranean facilities. Also, while certain data acquisition tools are depicted, it will be appreciated that various measurement tools capable of sensing parameters, such as seismic two-way travel time, density, resistivity, production rate, etc., of the subterranean formation and/or its geological formations may be used. Various sensors (S) may be located at various positions along the wellbore and/or the monitoring tools to collect and/or monitor the desired data. Other sources of data may also be provided from offsite locations.

The field configurations of FIGS. 2-5 are intended to provide a brief description of an example of a field usable with oilfield application frameworks. Part of, or the entirety, of oilfield 100 may be on land, water, and/or sea. Also, while a single field measured at a single location is depicted, oilfield applications may be utilized with any combination of one or more oilfields, one or more processing facilities and one or more wellsites.

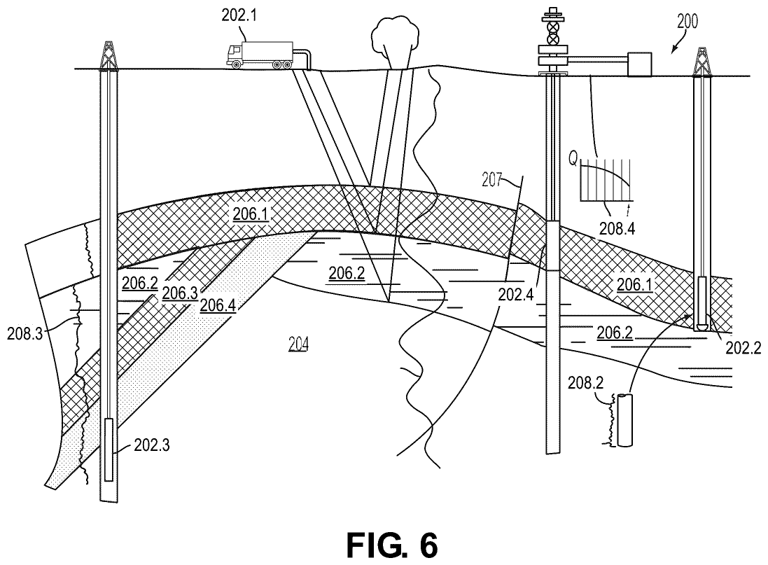

FIG. 6 illustrates a schematic view, partially in cross section of oilfield 200 having data acquisition tools 202.1, 202.2, 202.3 and 202.4 positioned at various locations along oilfield 200 for collecting data of subterranean formation 204 in accordance with implementations of various technologies and techniques described herein. Data acquisition tools 202.1-202.4 may be the same as data acquisition tools 106.1-106.4 of FIGS. 2-5, respectively, or others not depicted. As shown, data acquisition tools 202.1-202.4 generate data plots or measurements 208.1-208.4, respectively. These data plots are depicted along oilfield 200 to demonstrate the data generated by the various operations.

Data plots 208.1-208.3 are examples of static data plots that may be generated by data acquisition tools 202.1-202.3, respectively; however, it should be understood that data plots 208.1-208.3 may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 208.1 is a seismic two-way response over a period of time. Static plot 208.2 is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 208.3 is a logging trace that typically provides a resistivity or other measurement of the formation at various depths.

A production decline curve or graph 208.4 is a dynamic data plot of the fluid flow rate over time. The production decline curve typically provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 206.1-206.4. As shown, this structure has several formations or layers, including a shale layer 206.1, a carbonate layer 206.2, a shale layer 206.3 and a sand layer 206.4. A fault 207 extends through the shale layer 206.1 and the carbonate layer 206.2. The static data acquisition tools are adapted to take measurements and detect characteristics of the formations.

While a specific subterranean formation with specific geological structures is depicted, it will be appreciated that oilfield 200 may contain a variety of geological structures and/or formations, sometimes having extreme complexity. In some locations, typically below the water line, fluid may occupy pore spaces of the formations. Each of the measurement devices may be used to measure properties of the formations and/or its geological features. While each acquisition tool is shown as being in specific locations in oilfield 200, it will be appreciated that one or more types of measurement may be taken at one or more locations across one or more fields or other locations for comparison and/or analysis.

The data collected from various sources, such as the data acquisition tools of FIG. 6, may then be processed and/or evaluated. Typically, seismic data displayed in static data plot 208.1 from data acquisition tool 202.1 is used by a geophysicist to determine characteristics of the subterranean formations and features. The core data shown in static plot 208.2 and/or log data from well log 208.3 are typically used by a geologist to determine various characteristics of the subterranean formation. The production data from graph 208.4 is typically used by the reservoir engineer to determine fluid flow reservoir characteristics. The data analyzed by the geologist, geophysicist and the reservoir engineer may be analyzed using modeling techniques.

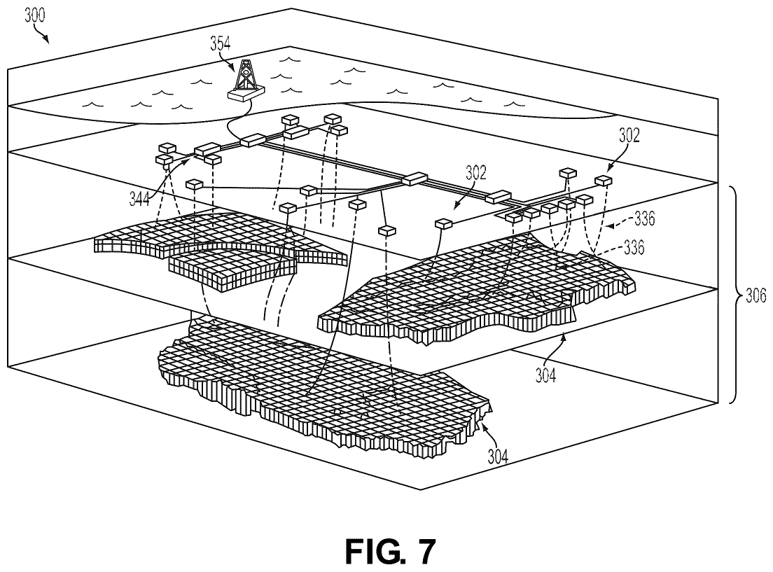

FIG. 7 illustrates an oilfield 300 for performing production operations in accordance with implementations of various technologies and techniques described herein. As shown, the oilfield has a plurality of wellsites 302 operatively connected to central processing facility 354.

The oilfield configuration of FIG. 7 is not intended to limit the scope of the oilfield application system. Part, or all, of the oilfield may be on land and/or sea. Also, while a single oilfield with a single processing facility and a plurality of wellsites is depicted, any combination of one or more oilfields, one or more processing facilities and one or more wellsites may be present.

Each wellsite 302 has equipment that forms wellbore 336 into the earth. The wellbores extend through subterranean formations 306 including reservoirs 304. These reservoirs 304 contain fluids, such as hydrocarbons. The wellsites draw fluid from the reservoirs and pass them to the processing facilities via surface networks 344. The surface networks 344 have tubing and control mechanisms for controlling the flow of fluids from the wellsite to processing facility 354.

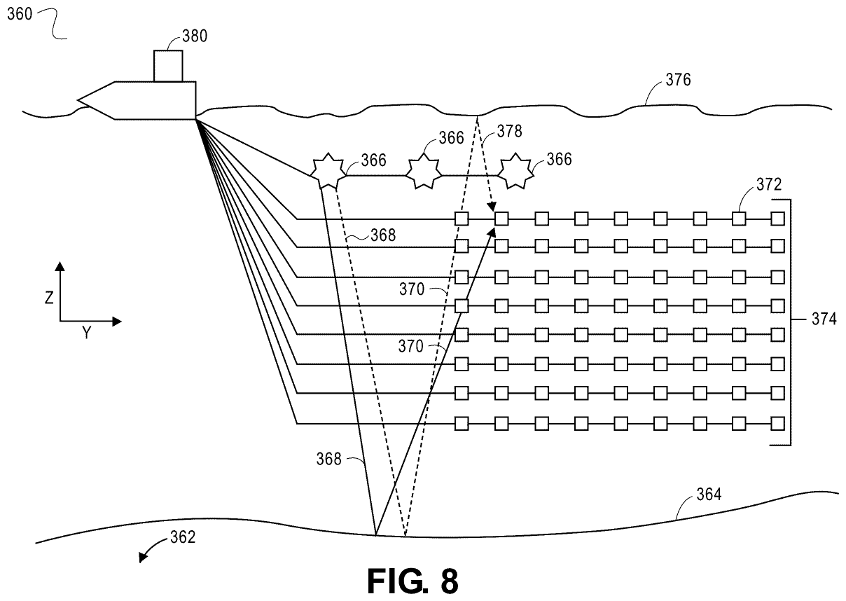

Attention is now directed to FIG. 8, which illustrates a side view of a marine-based survey 360 of a subterranean subsurface 362 in accordance with one or more implementations of various techniques described herein. Subsurface 362 includes seafloor surface 364. Seismic sources 366 may include marine sources such as vibroseis or airguns, which may propagate seismic waves 368 (e.g., energy signals) into the Earth over an extended period of time or at a nearly instantaneous energy provided by impulsive sources. The seismic waves may be propagated by marine sources as a frequency sweep signal. For example, marine sources of the vibroseis type may initially emit a seismic wave at a low frequency (e.g., 5 Hz) and increase the seismic wave to a high frequency (e.g., 80-98z) over time.

The component(s) of the seismic waves 368 may be reflected and converted by seafloor surface 364 (i.e., reflector), and seismic wave reflections 370 may be received by a plurality of seismic receivers 372. Seismic receivers 372 may be disposed on a plurality of streamers (i.e., streamer array 374). The seismic receivers 372 may generate electrical signals representative of the received seismic wave reflections 370. The electrical signals may be embedded with information regarding the subsurface 362 and captured as a record of seismic data.

In one implementation, each streamer may include streamer steering devices such as a bird, a deflector, a tail buoy and the like, which are not illustrated in this application. The streamer steering devices may be used to control the position of the streamers in accordance with the techniques described herein.

In one implementation, seismic wave reflections 370 may travel upward and reach the water/air interface at the water surface 376, a portion of reflections 370 may then reflect downward again (i.e., sea-surface ghost waves 378) and be received by the plurality of seismic receivers 372. The sea-surface ghost waves 378 may be referred to as surface multiples. The point on the water surface 376 at which the wave is reflected downward is generally referred to as the downward reflection point.

The electrical signals may be transmitted to a vessel 380 via transmission cables, wireless communication or the like. The vessel 380 may then transmit the electrical signals to a data processing center. Alternatively, the vessel 380 may include an onboard computer capable of processing the electrical signals (i.e., seismic data). Those skilled in the art having the benefit of this disclosure will appreciate that this illustration is highly idealized. For instance, surveys may be of formations deep beneath the surface. The formations may typically include multiple reflectors, some of which may include dipping events, and may generate multiple reflections (including wave conversion) for receipt by the seismic receivers 372. In one implementation, the seismic data may be processed to generate a seismic image of the subsurface 362.

Typically, marine seismic acquisition systems tow each streamer in streamer array 374 at the same depth (e.g., 5-10 m). However, marine based survey 360 may tow each streamer in streamer array 374 at different depths such that seismic data may be acquired and processed in a manner that avoids the effects of destructive interference due to sea-surface ghost waves. For instance, marine-based survey 360 of FIG. 8 illustrates eight streamers towed by vessel 380 at eight different depths. The depth of each streamer may be controlled and maintained using the birds disposed on each streamer.

Responsive to an assessed change in the subsurface fluid reservoir, e.g., a CO₂ plume body, a signal may either be generated by software or ordered by a human operator and then transmitted to the worksite. This signal may instruct that an action be performed at the worksite or may automatically result in the action being performed at the worksite. The worksite action may be a physical action to occur at the worksite at the CO₂ sequestration region. Such worksite actions may include: performing additional seismic measurements; repeating already conducted measurements; labelling the fluid reservoir; notifying regulators or other relevant entities regarding status of the worksite/reservoir; injecting additional fluids into the reservoir, including additional CO₂, or removing fluids from the reservoir; and taking other maintenance and/or monitoring actions appropriate to the fluid reservoir.

Attention is now directed to methods, techniques, and workflows for processing and/or transforming collected data that are in accordance with some embodiments. Some operations in the processing procedures, methods, techniques, and workflows disclosed herein may be combined and/or the order of some operations may be changed. Those with skill in the art will recognize that in the geosciences and/or other multi-dimensional data processing disciplines, various interpretations, sets of assumptions, and/or domain models such as velocity models, may be refined in an iterative fashion; this concept is applicable to the procedures, methods, techniques, and workflows as discussed herein. This iterative refinement can include use of feedback loops executed on an algorithmic basis, such as at a computing device (e.g., computing system 100, FIG. 1), and/or through manual control by a user who may make determinations regarding whether a given step, action, template, or model has become sufficiently accurate.

### Example of Integrated Workflow

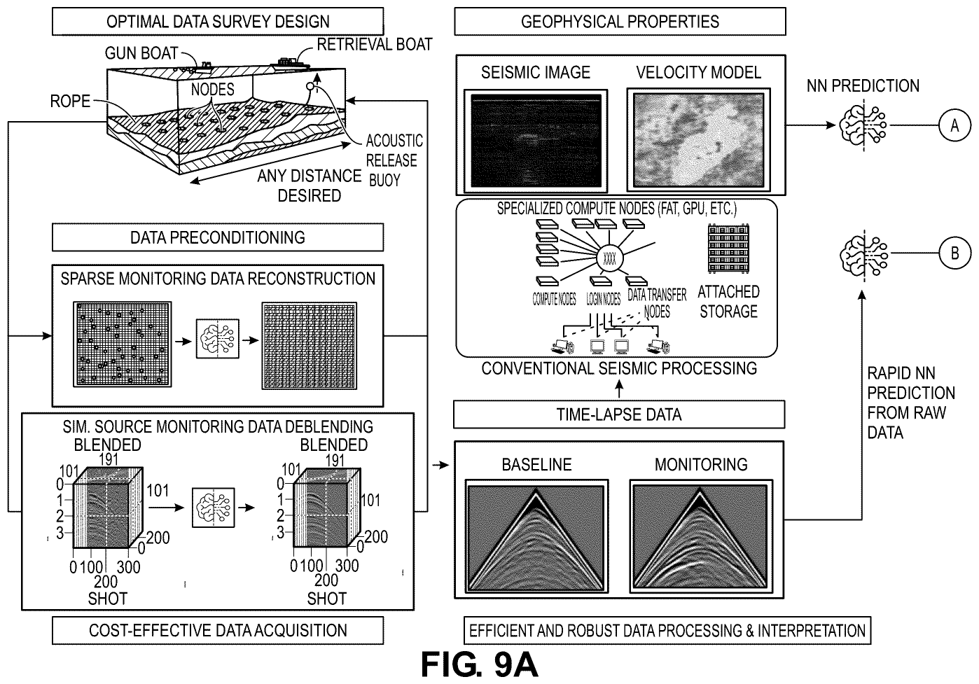

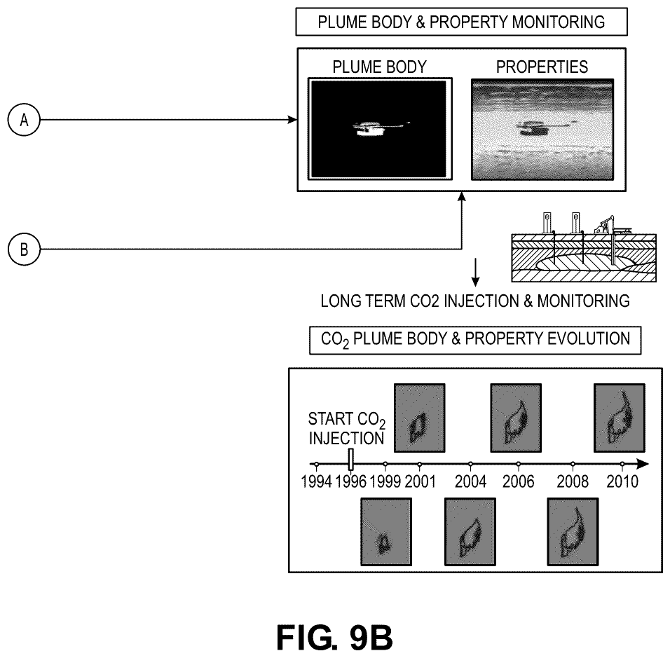

FIGS. 9A and 9B illustrate an example diagram of the integrated workflow. The integrated workflow consists of a suite of data-driven technologies that aims to substantially reduce the cost of monitoring data acquisition, improve the robustness and efficiency of time-lapse data processing procedures to shorten the turnaround time of CO₂ monitoring projects. As shown in FIGS. 9A and 9B, this workflow consists of two parts: (1) cost-effective data acquisition schemes and (2) efficient data processing algorithms. The technology components in the workflow include the following: (1) deep learning sparse monitoring data reconstruction and optimal acquisition survey design, (2) deep learning deblending of simultaneous source monitoring data, (3) time-lapse data repeatability enforcement through deep learning, and (4) rapid CO₂ plume body and property estimation directly from pre-migration monitoring data.

With regard to deep learning sparse monitoring data reconstruction and optimal acquisition survey design, the implementation of this technology component can reduce the number of source and receivers in a time-lapse monitoring data acquisition survey without losing the vital subsurface information, for example, in order to achieve adequate 4D time-lapse CO₂ monitoring accuracy. For example, the dense baseline data can be input into a convolutional neural network (CNN) to converge to the sparse monitoring data through a self-supervised learning process. With this strategy, the deep learning network can implicitly retrieve the subsurface geological information from the baseline data input to circumvent the aliasing problem, which is a well-known challenge in sparse data reconstruction. At the same time, the CNN gradually establishes a nonlinear mapping relationship from the baseline data to the monitoring data to satisfy the coherent requirement. An optimal sparse survey design can be recommended by testing this algorithm on multiple pre-designed sparse survey geometry plans.

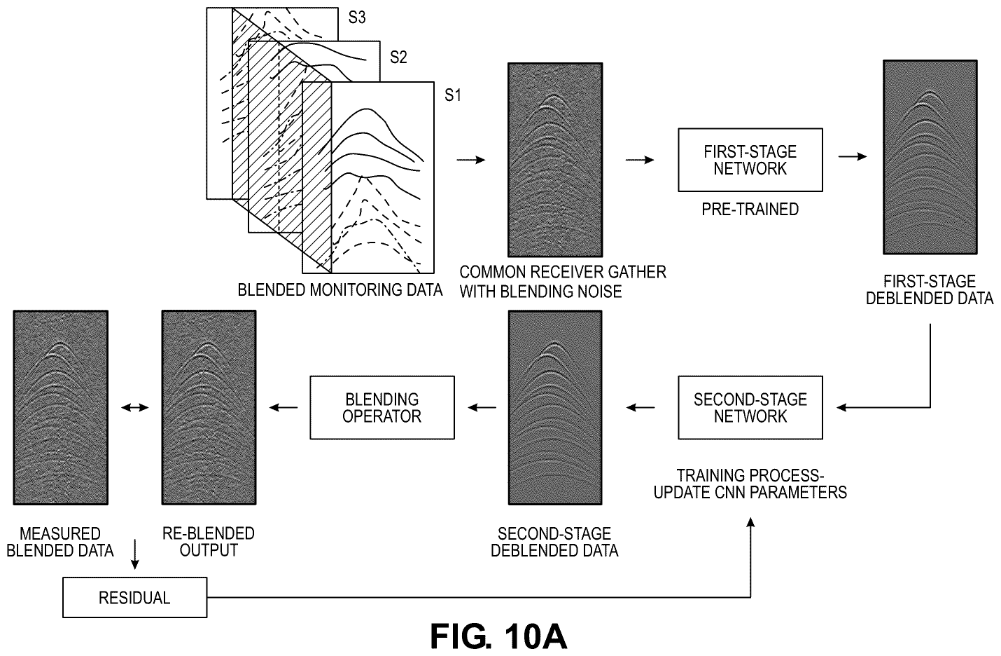

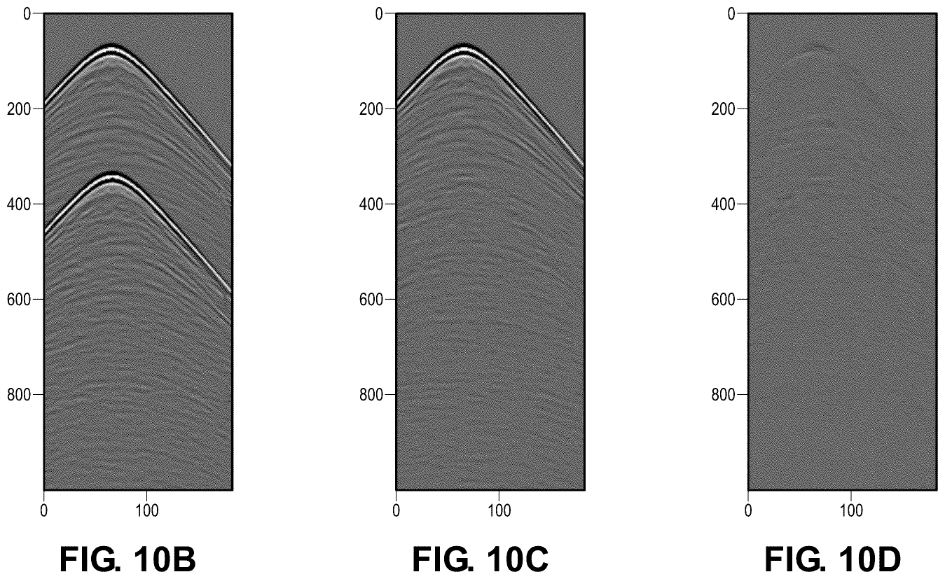

With regard to the deep learning deblending of simultaneous source monitoring data, the implementation of such technology component can more robustly and efficiently deblend data using deep learning. In some cases, a simultaneous shooting strategy can be employed to lower the cost of time-lapse monitoring data acquisition. Further, the implementation of a simultaneous shooting strategy can result in recorded signals that contain mixed contribution from multiple seismic sources, known as blended data. In order to separate the signals from different individual sources, a process known as deblending can be implemented. The technology component using deep learning is further described below in FIG. 10A.

With regard to the time-lapse data repeatability enforcement through deep learning, whereas non-repeatability between baseline data and monitoring data can be challenging in a time-lapse data processing, the implementation of such technology component can separate the baseline-monitoring data difference contributed by CO₂ injection and other factors, and the latter is eliminated by a deep learning network. For example, in this approach, the spatial domain can be decomposed into the CO₂ zone and non-CO₂ zone based on a priori information. A deep learning neural network is trained to push the monitoring data in non-CO₂ towards the non-CO₂ zone baseline data. This network, after a successful training process, is able to suppress the baseline-monitoring data difference caused by other factors such as near surface velocity change, seismic bandwidth difference, etc., while the contribution from the CO₂ injection is retained. The time-lapse measurement with this data repeatability enforcement procedure is more reliable and accurate.

With regard to the rapid CO₂ plume body and property estimation directly from pre-migration monitoring data, whereas conventional time-lapse data analysis for CO₂ monitoring can include a full seismic processing workflow, the implementation of such technology component (e.g., a deep learning network for rapid subsurface property change estimation directly from pre-migration data) can bypass computationally expensive and manually intensive procedures. For example, a network can be designed to build the nonlinear mapping between the depth domain property contrast and the time domain seismic response. The network can be trained by the baseline data and one set of monitoring data. After that, the network can make instantaneous prediction of the subsurface property change for any new monitoring dataset without conventional velocity model building and imaging process procedures. This algorithm is applicable to surface seismic data, VSP, cross-well data, or other types of geophysical data.

Further, assuming that the change in subsurface conditions over time is minimal, the network can transfer the knowledge learned from a baseline dataset to the monitoring datasets. Furthermore, the data-driven nature of deep learning enables accurate prediction without being affected by the limited knowledge of complicated behaviors of injected CO₂.

### Example Diagram of Network for Deblending

FIG. 10A illustrates an example diagram of a network for deblending data. A two-stage deep learning network is illustrated where in the first stage, the network learns the unblended baseline data and the numerically blended baseline data. As illustrated, the output of the first stage network is fed into the second stage, which is a self-supervised network, to finetune the deblending result by a blending loss function.

FIG. 10A represents a two-stage monitoring data deblending network. FIG. 10B represents the blended monitoring data (input of the network). FIG. 10C represents the deblended monitoring data. FIG. 10D represents output when an error is made.

### Example of Integrated Workflow

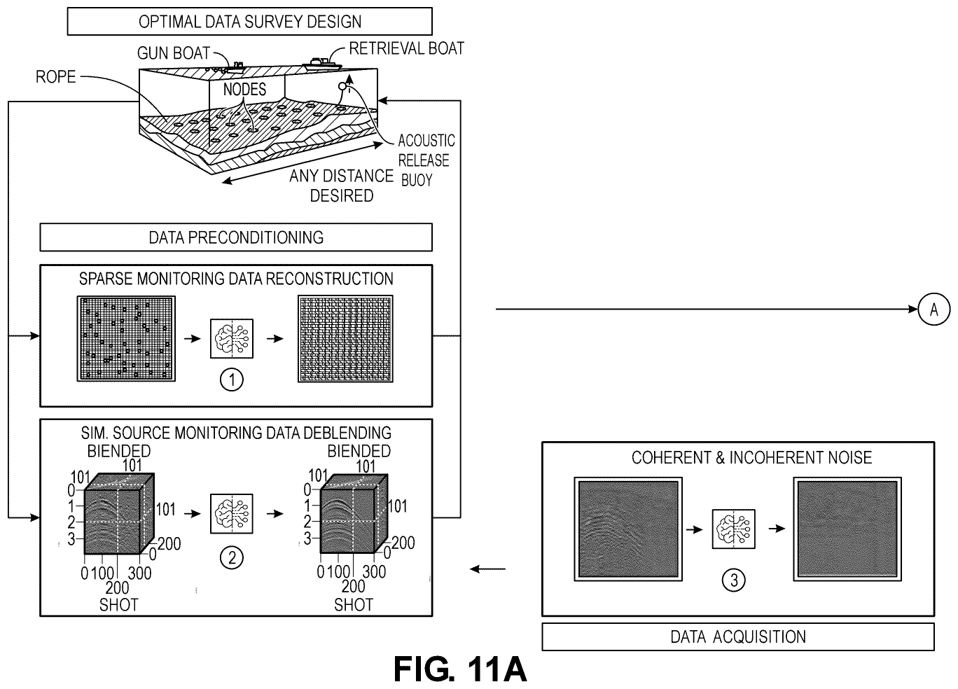

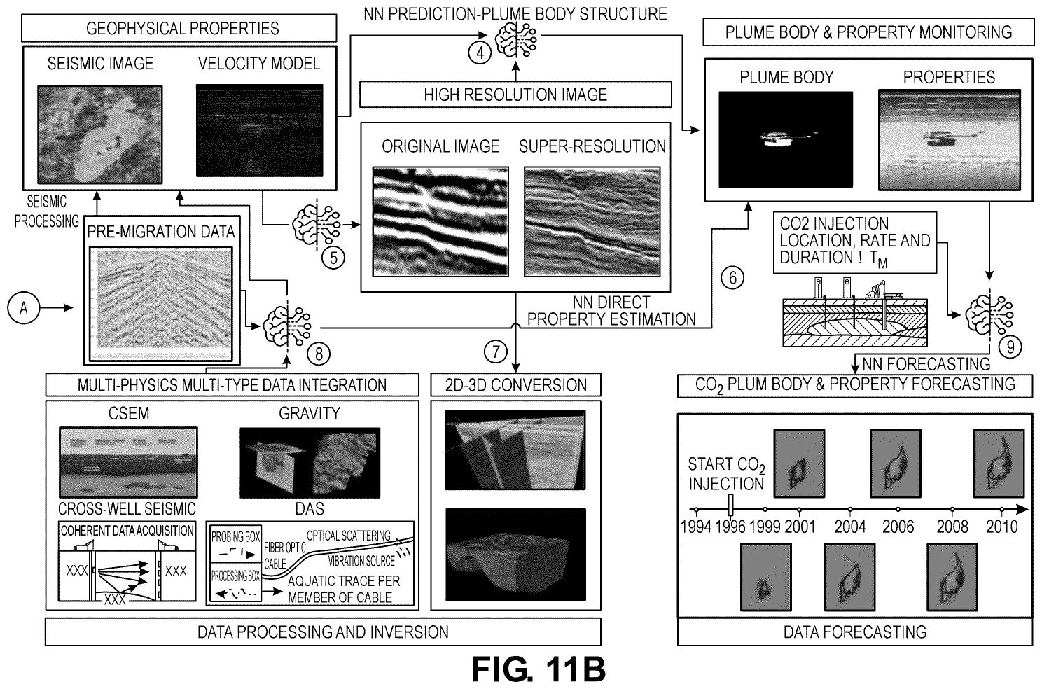

FIG. 11A and 11B illustrate an example diagram of an integrated workflow. The example diagram includes the following technology components: Technology component 1: Deep learning sparse monitoring data reconstruction and optimal acquisition survey design; Technology component 2: Deep learning deblending of simultaneous source monitoring data; Technology component 3: Deep learning algorithms for coherent and incoherent noise removal or suppression; Technology component 4: Automatic interpretation of subsurface CO₂ plume body and the corresponding subsurface property changes from seismic images; Technology component 5: Seismic image resolution enhancement for accurate CO₂ plume body interpretation; Technology component 6: Rapid CO₂ plume body and property estimation directly from pre-migration monitoring data; Technology component 7: Deep learning-based 2D-to-3D image conversion; Technology component 8: Multi-physics multi-type data integration; and Technology component 9: CO₂ plume body and property forecasting.

### Technology Component 1: Deep Learning Sparse Monitoring Data Reconstruction and Optimal Acquisition Survey Design

This deep learning-based technology can reduce the number of sources and receivers in a time-lapse monitoring data acquisition survey without losing the vital subsurface information. One way to achieve this is to reduce the number of sources and/or receivers in the spatial domain, e.g., in the AOI. This may be done by decimating the sources/receivers and decimating the data sent to or received from the sources/receivers. Further, this reduction and decimation may be implemented randomly or regularly.

### Technology Component 2: Deep Learning Deblending of Simultaneous Source Monitoring Data

To further lower the cost of time-lapse monitoring data acquisition, simultaneous shooting strategy is often employed, resulting in recorded signals that contains mixed contribution from multiple seismic sources, known as blended data. A process to separate the signals from different individual sources is called deblending. The implementation of such technology component can more robustly and efficiently deblend data using deep learning.

Examples of deep learning deblending of simultaneous source monitoring data may be found at U.S. Provisional Patent Application, 63/260,628, filed Aug. 27, 2021 and International Patent Application, PCT/US2022/075593, filed Aug. 29, 2022. Both of these applications are incorporated herein by reference, in their entireties.

### Technology Component 3: Deep Learning Algorithms for Coherent and Incoherent Noise Removal or Suppression

Recorded time-lapse data can be contaminated by various types of noises. These noises, especially those coherent, can have a negative impact on the accuracy of the time-lapse measure (i.e., the difference between the baseline data and the monitoring data). Removal or suppression of noises can result in more robust time-lapse analysis. As such, the implementation of this technology component includes use of deep learning algorithms to achieve this objective.

### Technology Component 4: Automatic Interpretation of Subsurface CO₂ Plume Body and the Corresponding Subsurface Property Changes from Seismic Images

A deep learning network can be implemented to analyze the seismic images obtained from the baseline data and the monitoring data to find the difference between these images, and then output the interpreted subsurface CO₂ plume body geometry or the subsurface properties associated with the CO₂ plume body. Unlike existing approaches, first time-lapse data repeatability enforcement can be applied to the images, and then input the repeatability enforced time-lapse seismic images to the network for automatic subsurface CO₂ plume body interpretation.

### Technology Component 5: Seismic Image Resolution Enhancement for Accurate CO₂ Plume Body Interpretation

Due to the bandlimited nature of seismic data, the resulting seismic images often have lower resolution than the CO₂ plume body structures. To better resolve the CO₂ plume body internal structure, a deep learning method can be implemented to enhance the seismic image resolution. Even where known convolutional neural network deep learning methods are utilized, techniques for building the training data and labels can result in improved methods and results.

### Technology Component 6: Rapid CO₂ Plume Body and Property Estimation Directly from Pre-Migration Monitoring Data

Whereas conventional time-lapse data analysis for CO₂ monitoring can include a full seismic processing workflow, the implementation of such technology component (e.g., a deep learning network for rapid subsurface property change estimation directly from pre-migration data) can bypass computationally expensive and manually intensive procedures. For example, a network can be designed to build the nonlinear mapping between the depth domain property contrast and the time domain seismic response. The network can be trained by the baseline data and one set of monitoring data. After that, the network can make instantaneous prediction of the subsurface property change for any new monitoring dataset without conventional velocity model building and imaging process procedures. This algorithm is applicable to surface seismic data, VSP, cross-well data, or other types of geophysical data.

### Technology Component 7: Deep Learning-Based 2D-to-3D Image Conversion

Seismic data acquisition is expensive, especially for 3D acquisitions. To reduce this cost, 2D seismic data can be acquired for monitoring surveys and then a deep learning approach can be implemented to construct a 3D image volume using these 2D images.

Examples of deep learning deblending of simultaneous source monitoring data may be found at U.S. Provisional Patent Application 63/469,697, filed May 30, 2023 and U.S. Provisional Application 63/471,180, filed Jun. 5, 2023. Both of these applications are incorporated herein by reference, in their entireties.

### Technology Component 8: Multi-Physics Multi-Type Data Integration

To improve the robustness of CO₂ monitoring, the technology component can be implemented such that deep learning can be used to integrate multi-physics data (e.g., CSEM data, gravity data, seismic data) or multi-type data (e.g., surface seismic, VSP, DAS, cross-well seismic) to monitor the subsurface CO₂ plume body and the associated properties.

### Technology Component 9: CO₂ Plume Body and Property Forecasting

Seismic data acquisition and the subsequent seismic data processing are both expensive, to further reduce the cost of CO₂ monitoring, after we acquired multiple monitoring datasets, future monitoring data acquisition can be bypassed. Instead, a deep learning approach can be implemented to forecast the future plume body geometry, migration, and the associated properties based on history matching.

The steps in the processing methods described above may be implemented by running one or more functional modules in information processing apparatus such as general-purpose processors or application specific chips, such as ASICs, FPGAs, PLDs, or other appropriate devices. These modules, combinations of these modules, and/or their combination with general hardware are included within the scope of protection.

Of course, many processing techniques for collected data, including one or more of the techniques and methods disclosed herein, may also be used successfully with collected data types other than seismic data. While certain implementations have been disclosed in the context of seismic data collection and processing, those with skill in the art will recognize that one or more of the methods, techniques, and computing systems disclosed herein can be applied in many fields and contexts where data involving structures arrayed in a multi-dimensional space and/or subsurface region of interest may be collected and processed, e.g., medical imaging techniques such as tomography, ultrasound, MRI and the like for human tissue; radar, sonar, and LIDAR imaging techniques; mining area surveying and monitoring, oceanographic surveying and monitoring, and other appropriate multi-dimensional imaging problems.

Many examples of equations and mathematical expressions have been provided in this disclosure. But those with skill in the art will appreciate that variations of these expressions and equations, alternative forms of these expressions and equations, and related expressions and equations that can be derived from the example equations and expressions provided herein may also be successfully used to perform the methods, techniques, and workflows related to the embodiments disclosed herein.

While any discussion of or citation to related art in this disclosure may or may not include some prior art references, applicant neither concedes nor acquiesces to the position that any given reference is prior art or analogous prior art.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to explain the principles of the invention and its practical applications, to thereby enable others skilled in the art to utilize the invention and various embodiments with various modifications as are suited to the particular use contemplated.

Those with skill in the art will appreciate that while the quoted sections of the article above that are provided for illustrative purposes include terms that could be interpreted as potentially absolute or requiring a given thing (including without limitation “exactly”, “exact”, “only”, “key”, “important”, “requires”, “all”, “each”, “must”, “always”, etc.), the various systems, methods, processing procedures, techniques, and workflows disclosed herein are not to be understood as limited by the use of these terms.

What is claimed is:

1. A method, comprising:
collecting a baseline dataset comprising seismic data for a subterranean formation that includes a fluid reservoir;
collecting an initial monitoring dataset comprising seismic data;
training a time-lapse fluid reservoir monitoring deep learning model with a set of inputs comprising the baseline dataset;
collecting a later monitoring dataset comprising seismic data at a time subsequent to the collection of the baseline dataset and initial monitoring dataset;
assessing, utilizing the time-lapse fluid reservoir monitoring deep learning model, a change in the fluid reservoir between the collection of either the baseline dataset or the initial monitoring dataset and the collection of the later monitoring dataset; and
displaying a data plot representing the change in the fluid reservoir.

2. The method of claim 1, wherein:
the training of the deep learning model and assessing using the deep learning model utilize a sparse monitoring data reconstruction and optimal acquisition survey design;
the deep learning model includes one or more algorithms for coherent and incoherent noise removal or suppression;
the deep learning model includes 2D-to-3D image conversion; and
the data plot includes an interpretation of a subsurface CO₂ plume body.

3. The method of claim 1, further comprising:
interpreting a subsurface CO₂ plume body based on the change in the fluid reservoir;
enhancing a resolution of the data plot to improve interpretation of the CO₂ plume body; and
integrating multi-physics and multi-type data to the deep learning model.

4. The method of claim 1, further comprising:
estimating a CO₂ plume body property from a pre-migration monitoring dataset, the estimation being rapid; and
forecasting the CO₂ plume body.

5. The method of claim 1, wherein the data plot representing the change in the fluid reservoir is a graphical display and the method further comprises:
performing a worksite action in response to the assessed change in the fluid reservoir, wherein the worksite action comprises generating and transmitting a signal that causes a physical action to occur at the fluid reservoir.

6. The method of claim 1, wherein the fluid reservoir is a carbon dioxide (CO₂) sequestration region.

7. The method of claim 1, wherein the fluid reservoir monitoring deep learning model is a convolutional neural network.

8. The method of claim 1, further comprising:
activating a plurality of seismic sources; and
recording, utilizing a plurality of receivers, signals from the seismic sources,
wherein the later monitoring dataset comprises the recorded signals.

9. The method of claim 8, further comprising:
training a deblending deep learning model to deblend the recorded signals, the deblending training including:
identifying a relation between an unblended monitoring signal and the recorded signals, wherein the relation is a deblended output;
providing the deblended output to a one of a supervised network, a self-supervised network or an unsupervised network that utilizes a blending loss function, wherein the result is a finetuned deblended output; and
deblending the recorded signals of the later monitoring dataset utilizing the deblending deep learning model, wherein the later monitoring dataset comprises the result of the deblending.

10. The method of claim 1, wherein the time that the later monitoring dataset is collected is at least one year subsequent to the collection of the baseline dataset.

11. The method of claim 1, further comprising:
reducing at least one of a data acquisition cost and a data processing cost by collecting initial monitoring and later monitoring datasets which are much smaller in size than the baseline dataset.

12. A computing system, comprising:
one or more processors; and
a memory system comprising one or more non-transitory computer-readable media storing instructions that, when executed by at least one of the one or more processors, cause the computing system to perform operations, the operations comprising:
collecting a baseline dataset comprising seismic data for a subterranean formation that includes a carbon dioxide (CO₂) sequestration region;
collecting an initial monitoring dataset comprising seismic data for the CO₂ sequestration region;
training a time-lapse fluid reservoir monitoring deep learning model with a set of inputs comprising the baseline dataset;
collecting a later monitoring dataset at a time subsequent to the collection of the baseline dataset and initial monitoring dataset;
assessing, utilizing the time-lapse fluid reservoir monitoring deep learning model, a change in the CO₂ sequestration region between the collection of either the baseline dataset or the initial monitoring dataset and the collection of the later monitoring dataset; and
displaying a data plot representing the change in the CO₂ sequestration region,
wherein collecting the baseline dataset, the initial monitoring dataset and the later monitoring dataset comprises activating one or more seismic sources and recording signals from the seismic sources at a plurality of receivers, wherein the baseline dataset, the initial monitoring dataset and the later monitoring dataset each comprises the recorded signals.

13. The computing system of claim 12, wherein the data plot representing the change in the CO₂ sequestration region is a graphical display and the method further comprises:
performing a worksite action in response to the assessed change in the CO₂ sequestration region, wherein the worksite action comprises generating and transmitting a signal that causes a physical action to occur at the CO₂ sequestration region.

14. The computing system of claim 12, wherein more receivers are used to record the baseline dataset than are used to record the initial monitoring dataset and the later monitoring dataset.

15. The computing system of claim 12, wherein the fluid reservoir monitoring deep learning model is a convolutional neural network.

16. The computing system of claim 12, wherein the recorded signals comprise blended signals from the one or more seismic sources, the method further comprising:
training a deblending deep learning model to deblend the recorded signals, the deblending training including:
identifying a relation between an unblended monitoring signal and the recorded signals, wherein the relation is a deblended output; and
providing the deblended output to one of a supervised network, a self-supervised network or an unsupervised network that utilizes a blending loss function, wherein the result is a finetuned deblended output;
deblending the recorded signals of the later monitoring dataset utilizing the deblending deep learning model.

17. The computing system of claim 12, wherein the time that later monitoring dataset is collected is at least one year subsequent to the collection of the baseline dataset.

18. The computing system of claim 12, wherein the operations further comprise:
reducing at least one of a data acquisition cost and a data processing cost by collecting initial monitoring and later monitoring datasets which are much smaller in size than the baseline dataset.

19. The computing system of claim 12, wherein assessing changes in the CO₂ sequestration region includes enhancing a resolution of a seismic image.

20. A non-transitory computer-readable medium storing instructions that, when executed by one or more processors of a computing system, cause the computing system to perform operations, the operations comprising:
collecting a dense baseline dataset comprising seismic data for a carbon dioxide (CO₂) sequestration region;
collecting an initial monitoring dataset comprising seismic data for the CO₂ sequestration region, wherein the initial monitoring dataset is smaller than the dense baseline dataset;
training a time-lapse CO₂ monitoring deep learning model with a set of inputs comprising the dense baseline dataset and the initial monitoring dataset, wherein the CO₂ monitoring deep learning model is a convolutional neural network;
collecting a later monitoring dataset at a time that is at least one year subsequent to the collection of the baseline dataset, wherein the later monitoring dataset comprises a plurality of recorded signals, wherein the later monitoring dataset is smaller than the dense baseline dataset;
training a two-stage deblending deep learning model to deblend the plurality of simultaneously recorded monitoring signals, the deblending training including:
identifying in a first stage of the two-stage deblending deep learning model a relation between an unblended monitoring signal and the simultaneously recorded monitoring signals, wherein the relation is a first stage deblended output; and
providing the first stage deblended output to a second stage of the two-stage deblending deep learning model, wherein the second stage is self-supervised;
deblending the plurality of seismic signals of the later monitoring dataset utilizing the two-stage deblending deep learning model to create a deblended later monitoring dataset;
assessing, utilizing the time-lapse CO₂ monitoring deep learning model, a change in a CO₂ plume body located in the CO₂ sequestration region between the collection of the dense baseline dataset and the collection of the later monitoring dataset, wherein the assessment includes seismic image resolution enhancement;
displaying the change in the CO₂ plume body; and
performing a worksite action in response to the assessed change in the CO₂ plume body, wherein the worksite action comprises generating and transmitting a signal that causes a physical action to occur at the CO₂ sequestration region.
